(19) United States
(12) Patent Application Publication
(10) Pub. No.: US 2014/0162398 A1
(43) Pub. Date: Jun. 12, 2014

(54) METHOD OF PREPARING NANO METAL SALT AND ABSORPTION LAYER OF SOLAR CELL UTILIZING THE NANO METAL SALT

(71) Applicant: Industrial Technology Research Institute, Chutung (TW)

(72) Inventor: Chien-Chih CHIANG, New Taipei City (TW)

(21) Appl. No.: 13/911,908

(22) Filed: Jun. 6, 2013

(30) Foreign Application Priority Data
Dec. 11, 2012 (TW) 101146535

(51) Int. Cl. H01L 31/032

(52) U.S. Cl. CPC H01L 31/0322
USPC 438/95; 423/419.1; 423/420; 423/420.2

(57) ABSTRACT

Disclosed is a method of preparing a nano metal salt, including providing a metal cation solution, and providing hydroxide anions and carbonate anions to the metal cation solution to precipitate a nano metal salt. The nano metal salt has the hydroxide anion and the carbonate anion. The nano metal salt can be used to prepare an absorption layer of a solar cell.

### CROSS REFERENCE TO RELATED APPLICATIONS

The present application is based on, and claims priority from, Taiwan Application Serial Number 101146535, filed on Dec. 11, 2012, the disclosure of which is hereby incorporated by reference herein in its entirety

### TECHNICAL FIELD

The technical field relates to a method of preparing a nano metal salt, and in particular, relates to an absorption layer of a solar cell utilizing the same.

### BACKGROUND

Solar energy has the most potential as an energy source due to its inexhaustibility, environmental friendly property, and global application without specific regional limitations. Accordingly, solar energy is a practicable, clean, and renewable energy type. Compared to the thickness (greater than 100 μm) of a wafer solar cell, the thin film solar cell includes an optotronic material with a thickness of less than 2 μm. If the optotronic material has high absorption coefficient, the amount of the optotronic material can be largely reduced. In the conventional thin film solar cells, a copper-indium-gallium-selenide (CIGS) absorption layer not only has a high absorption coefficient but also has a tunable composition for different band gaps and electrical properties. In addition, the CIGS solar cell has high optotronic conversion efficiency (about 20%) when compared to all thin film solar cells. The group IB-IIIA-VIA (CIGS/CIGSe) film and the group IB-IIB-IVA-VIA (CZTS/CZTSe) film of the solar cell include multi elements, which means sensitive element matching, a complex crystalline structure, and a difficult lattice matching between interferences. The preparation of the CIGS film and the CZTSe films require high precision, reproducibility, and stability. The preparation of the absorption layer of the solar cell can be classified as a vacuum process and non-vacuum process. The vacuum process can be sputtering, co-evaporation, and the likes. The non-vacuum process can be electro-deposition, coating, spray pyrolysis, and the likes. The vacuum process costs are high, and a low-cost non-vacuum process has therefore been developed. The major non-vacuum process is slurry coating, and the critical points thereof are precisely controlling composition, manner, and size of the CIGS nano particles, uniformly dispersing the CIGS nanoparticles in the slurry, and simplifying the complex and energy-consuming processes (e.g. decarbonization and chemical reduction) after coating the slurry.

### SUMMARY

One embodiment of the disclosure provides a method of preparing a nano metal salt, comprising: providing a metal cation solution; and providing hydroxide anions and carbonate anions to the metal cation solution to precipitate a nano metal salt, wherein the nano metal salt has the hydroxide anion and the carbonate anion.

One embodiment of the disclosure provides a method of forming an absorption layer of a solar cell, comprising: providing a slurry of a nano metal salt composed of metal cation, hydroxide anion, and carbonate anion; coating the slurry on a substrate; drying the slurry to form a layer of the nano metal salt on the substrate; and selenizing the layer of the nano metal salt to form an absorption layer of a solar cell.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows an XRD spectrum of Cu₂(OH)₂CO₃ in one embodiment of the disclosure;

FIG. 2 shows an XRD spectrum of NH₄Ga(OH)(CO₃) in one embodiment of the disclosure;

FIG. 3 shows an XRD spectrum of NH₄Al(OH)CO₃ in one embodiment of the disclosure;

FIG. 4 shows an XRD spectrum of In(OH)₃*XCO₃ (0<X≦3) in one embodiment of the disclosure;

FIG. 5 shows an XRD spectrum of (NH₄)₂Cu₂InGa(OH)₆(CO₃)₃ in one embodiment of the disclosure;

FIG. 6 shows an XRD spectrum of Zn₅(OH)₆(CO₃)₂ in one embodiment of the disclosure;

FIG. 7 shows an XRD spectrum of Sn₆O₄(OH)₄*XCO₃ (0<X≦3) in one embodiment of the disclosure;

FIG. 8 shows an XRD spectrum of (NH₄)₂Cu₂InGa(OH)₆(CO₃)₃ in one embodiment of the disclosure;

FIG. 9 shows an XRD spectrum of Cu₅Zn_{(5-2.5x)}Sn_{2.5x}(OH)₉(CO₃)₃ in one embodiment of the disclosure; and

FIG. 10 shows an IV curve of a solar cell in one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In one embodiment, the nano metal salt is prepared as below. First, the metal cation solution is provided. The metal cation can be group IB metal ion (e.g. copper ion), group IIB metal ion (e.g. zinc ion), group IIIA metal ion (e.g. indium ion or gallium ion), group IVA metal ion (e.g. tin ion), or combinations thereof. The metal cation solution can be formed by directly dissolving a water-soluble metal salt in water. Alternatively, the metal can be dissolved in an acid such as oxalic acid, acetic acid, other common organic acids, hydrochloric acid, sulfuric acid, nitric acid, other common inorganic acid, or combinations thereof to form the metal cation solution.

Subsequently, hydroxide anions and carbonate anions are provided to the metal cation solution, such that the hydroxide anions, the carbonate anions, and the metal cations are precipitated to form the nano metal salt. The hydroxide anions and carbonate anions can be provided to the metal cation solution by bubbling a gas (e.g. carbon monoxide, carbon dioxide, and/or ammonia) into the metal cation solution, and/or adding a solution of the hydroxide anions and the carbonate anions (e.g. ammonium hydrocarbonate solution, lithium hydrocarbonate solution, sodium hydrocarbonate solution, potassium hydrocarbonate solution, ammonium carbonate solution, lithium carbonate solution, sodium carbonate solution, potassium carbonate solution, or combinations thereof) into the metal cation solution. It should be understood that the precipitated nano metal salt includes the hydroxide anion and the carbonate anion. In one embodiment, the nano metal salt has a size of 1 nm to 500 nm. Alternatively, the nano metal salt has a size of 1 nm to 100 nm.

In one embodiment, the metal cation is copper ion, and the nano metal salt is Malachite (Cu₂(OH)₂CO₃) or Azurite (Cu₃(OH)₂(CO₃)₂). In one embodiment, the metal cation is gallium ion, and the nano metal salt is Gallium Dawsonite (NH₄Ga(OH)₂CO₃). In one embodiment, the metal cation is aluminum, and the nano metal salt is Aluminum Dawsonite (NH₄Al(OH)₂CO₃). In one embodiment, the metal cation is indium ion, and the nano metal salt is In(OH)₃*XCO₃, wherein 0<X≦3. In one embodiment, the metal cation is zinc ion, and the nano metal salt is Sciarite (Zn₇(OH)₁₀(CO₃)₂), Hydrozincite (Zn₅(OH)₆(CO₃)₂), or Zn₄CO₃(OH)₆*H₂O. In one embodiment, the metal cation is tin ion, and the nano metal salt is Sn₆O₄(OH)₄*XCO₃ (0<X≦3), Na₂Sn₂(OH)₄, Na₂Sn(OH)₆, or K₂Sn(OH)₆. In one embodiment, the metal cation is a combination of copper ion, indium ion, and gallium ion, and the nano metal salt is (NH₄)₂Cu₂In₍₂₋ₓ₎Ga₂ₓ(OH)₆(CO₃)O₃, wherein 0≦x≦2. In one embodiment, the metal cation is a combination of copper ion, zinc ion, and tin ion, and the nano metal salt is Cu₅Zn_{(5-2.5x)}Sn_{2.5x}(OH)₉(CO₃)₃, wherein 0≦x≦2.

In one embodiment, the nano metal salt can be used to from an absorption layer of a solar cell. For example, a copper-containing nano metal salt such as Cu₂(OH)₂CO₃ and/or Cu₃(OH)₂(CO₃)₂, a indium-containing nano metal salt such as In(OH)₃*XCO₃ (023 X≦3), a gallium-containing metal salt such as NH₄Ga(OH)₂CO₃ were weighted according to the element ratio of a desired CIGS layer, and then uniformly dispersed in a slurry. The slurry is coated on a substrate and dried, and then put into a selenization furnace to selenize the coating for forming the CIGS layer. In another embodiment, copper ion, indium ion, and gallium ion of appropriate ratios are directly used to prepare a nano metal salt containing copper, indium, and gallium (e.g. (NH₄)₂Cu₂In₍₂₋ₓ₎Ga₂ₓ(OH)₆(CO₃)₃, wherein 0≦x≦2). The slurry of the nano metal salt is coated on a substrate and dried, and then put into a selenization furnace to selenize the coating for forming the CIGS layer. Another absorption layer such as CZTSe of a solar cell can be manufactured by similar processes. For example, a copper-containing nano metal salt such as Cu₂(OH)₂CO₃ and/or Cu₃(OH)₂(CO₃)₂, a zinc-containing nano metal salt such as Sciarite (Zn₇(OH)₁₀(CO₃)₂), Hydrozincite (Zn₅(OH)₆(CO₃)₂), and/or Zn₄CO₃(OH)₆*H₂O, a tin-containing metal salt such as Sn₆O₄(OH)₄*XCO₃ (0<X≦3) were weighted according to the element ratio of a desired CZTSe layer, and then uniformly dispersed in a slurry. The slurry is coated on a substrate and dried, and then put into a selenization furnace to selenize the coating for forming the CZTSe layer. In another embodiment, copper ion, zinc ion, and tin ion of appropriate ratios are directly used to prepare a nano metal salt containing copper, zinc, and tin (e.g. Cu₅Zn_{(5-2.5x)}Sn_{2.5x}(OH)₉(CO₃)₃, wherein 0≦x≦2). The slurry of the nano metal salt is coated on a substrate and dried, and then put into a selenization furnace to selenize the coating for forming the CZTSe layer. Compared to conventional processes, the nano metal salt layer can be directly selenized without further chemical reduction (e.g. hydrogenation) before the selenization. In other words, forming the absorption layer from the nano metal salt is simplified.

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

### Example 1

### Preparation of Cu₂(OH)₂CO₃

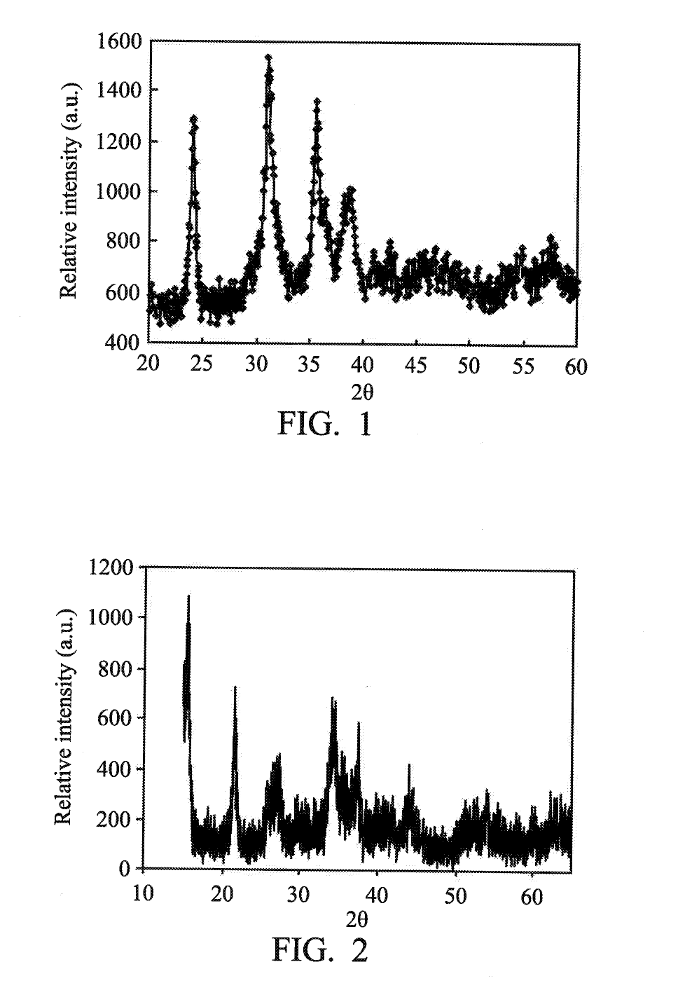

0.5 mole of copper nitrate and 2 mole of ammonium hydrocarbonate were dissolved in water to form solutions, respectively. The copper nitrate solution and the ammonium hydrocarbonate solution were mixed to precipitate a solid. The solid was collected by centrifugation, then washed by water to remove excess anions thereof, and then dried to obtain Cu₂(OH)₂CO₃. The XRD spectrum of the Cu₂(OH)₂CO₃ is shown as FIG. 1.

### Example 2

### Preparation of NH₄Ga(OH)(CO₃)

0.5 mole of gallium nitrate and 2 mole of ammonium hydrocarbonate were dissolved in water to form solutions, respectively. The gallium nitrate solution and the ammonium hydrocarbonate solution were mixed to precipitate a solid. The solid was collected by centrifugation, then washed by water to remove excess anions thereof, and then dried to obtain NH₄Ga(OH)(CO₃). The XRD spectrum of the NH₄Ga(OH)(CO₃) is shown as FIG. 2.

### Example 3

### Preparation of NH₄Al(OH)CO₃

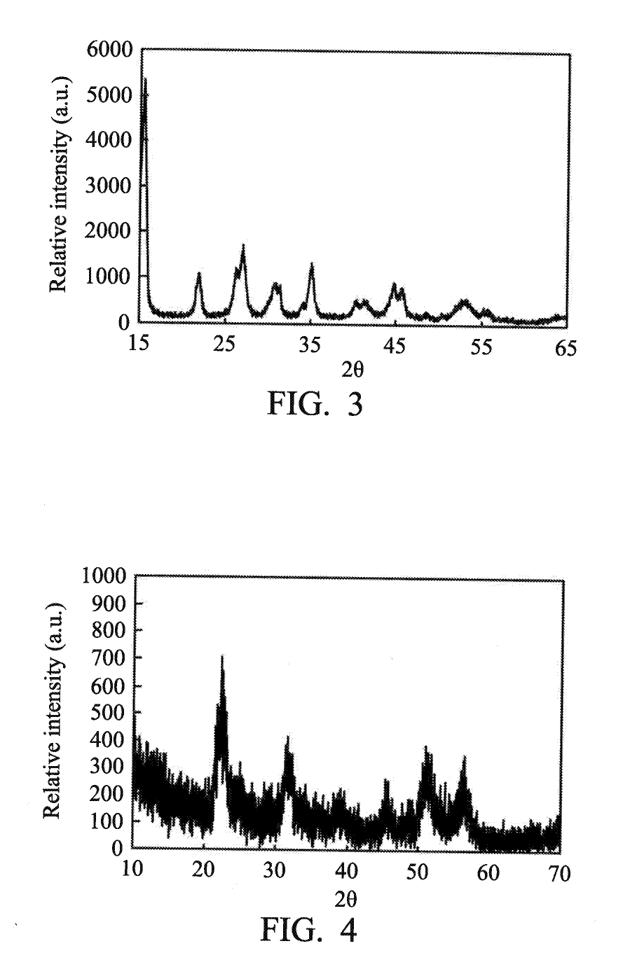

0.5 mole of aluminum nitrate and 2 mole of ammonium hydrocarbonate were dissolved in water to form solutions, respectively. The aluminum nitrate solution and the ammonium hydrocarbonate solution were mixed to precipitate a solid. The solid was collected by centrifugation, then washed by water to remove excess anions thereof, and then dried to obtain NH₄Al(OH)(CO₃). The XRD spectrum of the NH₄Al(OH)(CO₃) is shown as FIG. 3.

### Example 4

### Preparation of In(OH)₃*XCO₃, 0<X≦3

0.5 mole of indium nitrate and 2 mole of ammonium hydrocarbonate were dissolved in water to form solutions, respectively. The indium nitrate solution and the ammonium hydrocarbonate solution were mixed to precipitate a solid. The solid was collected by centrifugation, then washed by water to remove excess anions thereof, and then dried to obtain In(OH)₃*XCO₃ (0<X≦3). The XRD spectrum of the In(OH)₃*XCO₃ (0<X≦3) is shown as FIG. 4. Because the carbonate ions adsorbed on the nano metal salt had different decomposition and desorption rate, the X value could not be exactly measured. However, the carbonate ion might exist (X>0) and be less than or equal to 3 molar parts (X≦3).

### Example 5

### Preparation of Nano Metal Salt Containing Copper, Indium, and Gallium

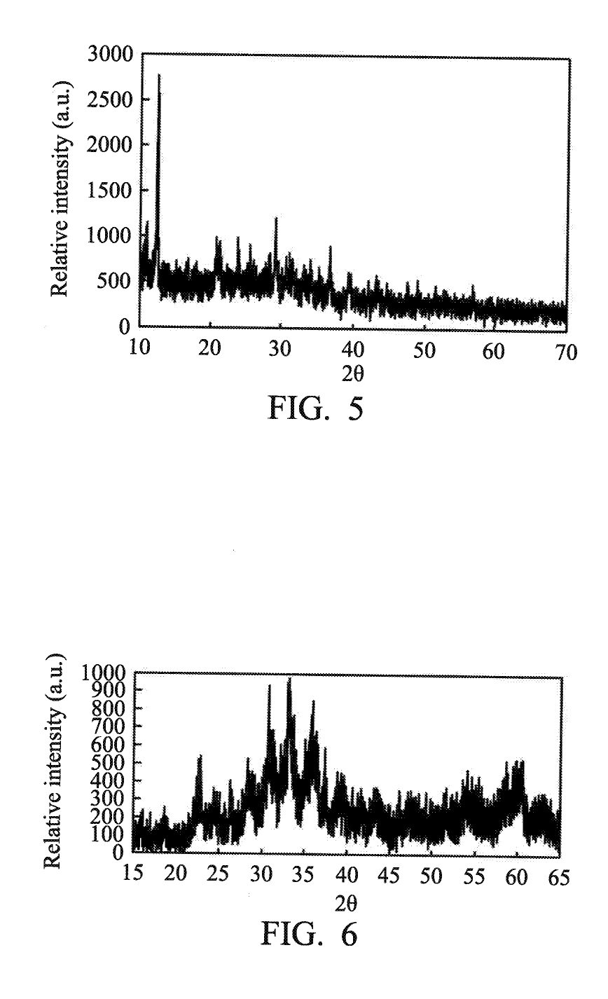

0.5 mole of copper nitrate, 0.25 mole of indium nitrate, and 2 mole of ammonium hydrocarbonate were dissolved in water to form solutions, respectively. The copper nitrate solution, the indium nitrate solution, and the ammonium hydrocarbonate solution were mixed to precipitate a solid. The solid was collected by centrifugation, then washed by water to remove excess anions thereof, and then dried to obtain (NH₄)₂InGa(OH)₆(CO₃)₃. The XRD spectrum of the (NH₄)₂Cu₂InGa(OH)₆(CO₃)₃ is shown as FIG. 5.

### Example 6

### Preparation of Nano Metal Salt Containing Zinc

0.5 mole of zinc nitrate and 2 mole of ammonium hydrocarbonate . were dissolved in water to form solutions, respectively. The zinc nitrate solution and the ammonium hydrocarbonate solution were mixed to precipitate a solid. The solid was collected by centrifugation, then washed by water to remove excess anions thereof, and then dried to obtain Hydrozincite (Zn₅(OH)₆(CO₃)₂). The XRD spectrum of the Zn₅(OH)₆(CO₃)₂ is shown as FIG. 6.

### Example 7

### Preparation of Nano Metal Salt Containing Zinc

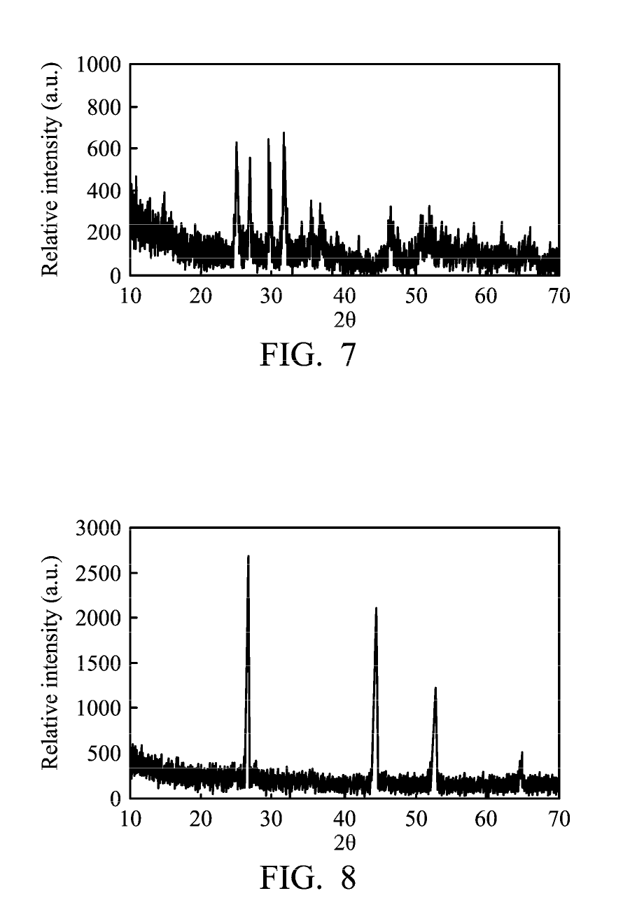

0.2 mole of tin chloride and 2 mole of ammonium hydrocarbonate were dissolved in water to form solutions, respectively. The tin chloride solution and the ammonium hydrocarbonate solution were mixed to precipitate a solid. The solid was collected by centrifugation, then washed by water to remove excess anions thereof, and then dried to obtain Hydrozincite Sn₆O₄(OH)₄*XCO₃ (0<X≦3). The XRD spectrum of the Sn₆O₄(OH)₄*XCO₃ (0<X≦3) is shown as FIG. 7. Because the carbonate ions adsorbed on the nano metal salt had different decomposition and desorption rate, the X value could not be exactly measured. However, the carbonate ion might exist (X>0) and be less than or equal to 3 molar parts (X≦3).

### Example 8

### Preparation of CMS Film from the Nano Metal Salt Containing Copper, Indium, and Gallium

0.5 mole of copper nitrate, 0.25 mole of indium nitrate, and 2 mole of ammonium hydrocarbonate were dissolved in water to form solutions, respectively. The copper nitrate solution, the indium nitrate solution, and the ammonium hydrocarbonate solution were mixed to precipitate a solid (nano particles). The solid was collected by centrifugation, and then washed by water to remove excess anions thereof. A slurry containing the solid (NH₄)₂Cu₂InGa(OH)₆(CO₃)₃ was coated on a molybdenum glass, then dried at a low temperature of about 60° C., and then put into a tube furnace for selenization. The film was selenized under 20% H₂Se at 550° C. for 30 minutes to obtain a copper-indium-gallium-selenide (CIGS) film. The XRD spectrum of the CIGS film is shown as FIG. 8.

Example 9

### Preparation of CZTSe Film from the Nano Metal Salt Containing Copper, Zinc, and Tin

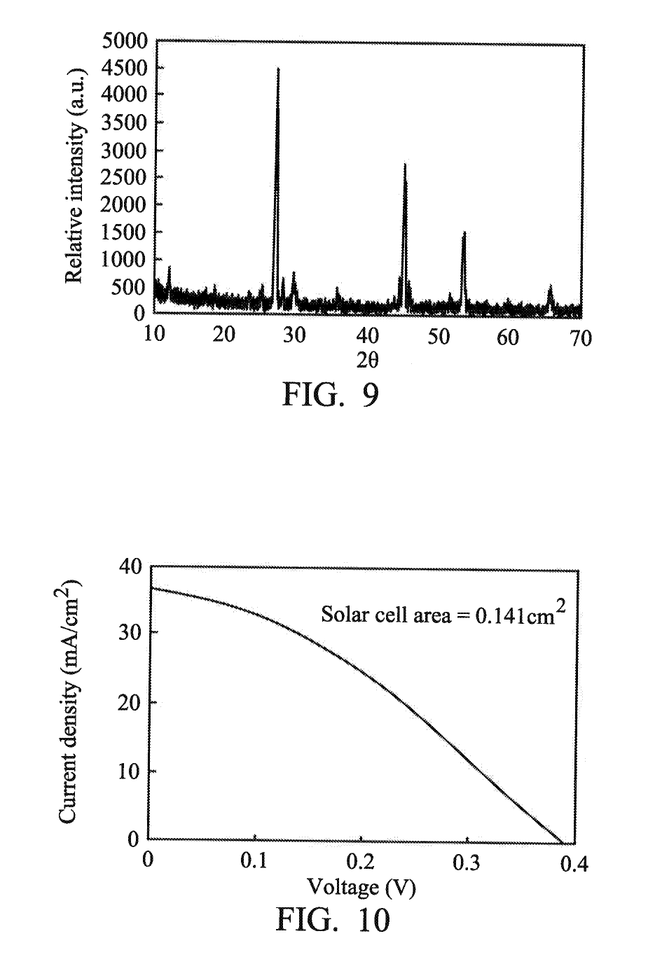

0.1224 mole of copper nitrate, 0.0644 mole of zinc nitrate, 0.0644 mole of tin chloride, and 2 mole of ammonium hydrocarbonate were dissolved in water to form solutions, respectively. The copper nitrate solution, the zinc nitrate solution, the tin chloride solution, and the ammonium hydrocarbonate solution were mixed to precipitate a solid (nano particles). The solid was collected by centrifugation, and then washed by water to remove excess anions thereof. A slurry containing the solid Cu₅Zn_{2.5}Sn_{2.5}(OH)₉(CO₃)₃ was coated on a molybdenum glass, then dried at a low temperature of about 60° C., and then put into a tube furnace for selenization. The film was selenized under 20% H₂Se at 550° C. for 30 minutes to obtain a copper-zinc-tin-selenide (CZTSe) film. The XRD spectrum of the CZTSe film is shown as FIG. 9.

### Example 10

### Preparation of CIGSe Film from Cu₂(OH)₂CO₃, NH₄Ga(OH)(CO₃), and In(OH)₃*XCO₃ (0≦X≦3)

0.284 mole of Cu₂(OH)₂CO₃, 0.237 mole of In(OH)₃*XCO₃ (0<X≦3), 0.948 mole of NH₄Ga(OH)(CO₃), and 2 mole of ammonium hydrocarbonate dissolved in water to form solutions, respectively. The Cu₂(OH)₂CO₃ solution, the n(OH)₃*XCO₃ (0<X≦3) solution, the NH₄Ga(OH)(CO₃) solution, and the ammonium hydrocarbonate solution were mixed to precipitate a solid (nano particles). The solid was collected by centrifugation, and then washed by water to remove excess anions thereof. A slurry containing the solid (NH₄)₂Cu₂InGa(OH)₆(CO₃)₃ was coated on a molybdenum glass, then dried at a low temperature of about 60° C., and then put into a tube furnace for selenization. The film was selenized under 20% H₂Se at 550° C. for 30 minutes to obtain a copper-indium-gallium-selenide (CIGSe) film. A CdS buffer layer with a thickness of 75 nm, a ZnO layer with a thickness of 50 nm, and 400 nm of a transparent conductive layer AZO (ZnO:Al) were sequentially coated on the CIGSe film. A silver electrode layer was screen printed on the AZO to complete a solar cell. The solar cell had an energy conversion efficiency of 4.9% under a light source of 1000 W/m². The solar cell had the IV curve as shown in FIG. 10, and other optotronic properties as shown in Table 1.

TABLE 1

| Open circuit | Short circuit current | | Conversion |
|---|---|---|---|
| voltage (Voc) | density (Jsc) | Filling factor (FF) | efficiency |
| 0.39 V | 36.47 mA/cm² | 34% | 4.934% |

It will be apparent to those skilled in the art that various modifications and variations can be made to the disclosed methods and materials. It is intended that the specification and examples be considered as exemplary only, with a true scope of the disclosure being indicated by the following claims and their equivalents.

What is claimed is:

1. A method of preparing a nano metal salt, comprising:
providing a metal cation solution; and
providing hydroxide anions and carbonate anions to the metal cation solution to precipitate a nano metal salt,
wherein the nano metal salt has the hydroxide anion and the carbonate anion.

2. The method as claimed in claim 1, wherein the metal cation comprises a group IB metal ion, a group IIIA metal ion, a group IIB metal ion, a group IVA metal ion, or combinations thereof.

3. The method as claimed in claim 1, wherein the nano metal salt comprises Cu₂(OH)₂CO₃, Cu₃(OH)₂(CO₃)₂, NH₄Ga(OH)₂CO₃, NH₄Al(OH)₂CO₃, In(OH)₃*XCO₃ (0<X≦3), Zn₇(OH)₁₀(CO₃)₂, Zn₅(OH)₆(CO₃)₂, Zn₄CO₃(OH)₆*H₂O, Sn₆O₄(OH)₄*XCO₃ (0<X≦3), Na₂Sn₂(OH)₄, K₂Sn(OH)₆, Na₂Sn(OH)₆, (NH₄)₂Cu₂In₍₂₋ₓ₎Ga₂ₓ(OH)₆(CO₃)₃ (0≦x≦2), or Cu₅Zn_{(5-2.5x)}Sn_{2.5x}(OH)₉(CO₃)₃ (023 x≦2).

4. The method as claimed in claim 1, wherein the step of providing the metal cation solution comprises dissolving a metal in an acid, and the acid comprises acetic acid, oxalic acid, hydrochloric acid, sulfuric acid, nitric acid, or combinations thereof.

5. The method as claimed in claim 1, wherein the step of providing the metal cation solution comprises dissolving a metal salt in water.

6. The method as claimed in claim 1, wherein the step of providing hydroxide anions and carbonate anions to the metal cation solution comprises:
bubbling a gas into the metal cation solution; and/or
adding a solution of the hydroxide anions and the carbonate anions into the metal cation solution.

7. The method as claimed in claim 6, wherein the gas comprises carbon monoxide, carbon dioxide, ammonia, or combinations thereof.

8. The method as claimed in claim 6, wherein the solution of the hydroxide anions and the carbonate anions comprises ammonium hydrocarbonate solution, lithium hydrocarbonate solution, sodium hydrocarbonate solution, potassium hydrocarbonate solution, or combinations thereof.

9. The method as claimed in claim 1, wherein the nano metal salt has a size of 1 nm to 500 nm.

10. A method of forming an absorption layer of a solar cell, comprising:
providing a slurry of a nano metal salt composed of metal cation, hydroxide anion, and carbonate anion;
coating the slurry on a substrate;
drying the slurry to form a layer of the nano metal salt on the substrate; and
selenizing the layer of the nano metal salt to form an absorption layer of a solar cell.

11. The method as claimed in claim 10, wherein the metal cation comprises a group IB metal ion, a group IIIA metal ion, a group IIB metal ion, a group IVA metal ion, or combinations thereof.

12. The method as claimed in claim 10, wherein the absorption layer of the solar cell is copper-indium-gallium-selenide layer or a copper-zinc-tin-selenide layer.

13. The method as claimed in claim 10, wherein no chemical reduction is performed for the layer of the nano metal salt before the step of selenizing the layer of the nano metal salt.
